(19) United States
(12) Patent Application Publication
(10) Pub. No.: US 2024/0260325 A1
(43) Pub. Date: Aug. 1, 2024

(54) LIGHT EMITTING DISPLAY DEVICE

(71) Applicant: LG Display Co., Ltd., Seoul (KR)

(72) Inventors: Yong Cheol KIM, Paju-si (KR); Mi Na KIM, Paju-si (KR)

(21) Appl. No.: 18/396,659

(22) Filed: Dec. 26, 2023

(30) Foreign Application Priority Data
Jan. 30, 2023 (KR) 10-2023-0012182

(51) Int. Cl. H10K 59/122; H10K 59/35; H10K 59/80

(52) U.S. Cl. CPC H10K 59/122; H10K 59/353; H10K 59/80518

(57) ABSTRACT

Disclosed is a light emitting display device including a substrate on which first to third sub-pixels are provided, and first to third light emitting devices that are respectively provided in the first to third sub-pixels to emit light of different wavelengths. The first to third light emitting devices each include first to third intermediate layers between a first electrode and a second electrode that face each other. The first to third intermediate layers include a red light emitting layer, a green light emitting layer, and a blue light emitting layer in order on the first electrode, in which the blue light emitting layer of the first intermediate layer has a vertical phase higher than those of the blue light emitting layers of the second and third intermediate layers.

### CROSS-REFERENCE TO RELATED APPLICATION(S)

This application claims the benefit of Korean Patent Application No. 10-2023-0012182, filed on Jan. 30, 2023, which is hereby incorporated by reference as if fully set forth herein.

### BACKGROUND

### Technical Field

The present disclosure relates to a light emitting display device, and more particularly, to a light emitting display device capable of extending a light emitting part to an area that overlaps a bank and preventing color mixing between adjacent light emitting parts.

### Description of the Related Art

With the development of information technology, demand for image display devices in various forms is increasing.

A light emitting display device in which light emitting devices are included in pixels does not include a separate light source, and is thus advantageous in slimness or flexibility, and has an advantage of good color purity.

Such a light emitting device includes two different electrodes and a light emitting layer provided therebetween in which, when electrons generated from one electrode and holes generated from the other electrode are injected into the light emitting layer, the injected electrons and holes are combined to generate excitons, and when the generated excitons fall from an excited state to a ground state, light emission occurs.

In the light emitting display device, a bank is provided to define a light emitting part of each sub-pixel, but light emission does not occur in an area occupied by the bank, which results in resolution limitations.

### BRIEF SUMMARY

Accordingly, the present disclosure is directed to providing a light emitting display device that substantially obviates one or more problems due to limitations and disadvantages of the related art.

A light emitting display device is capable of solving the above-mentioned problems by forming a side mirror connected to a first electrode (anode) in a bank to widen a light emitting part.

Further, a light emitting display device having a side mirror is capable of preventing color mixing by adjacent light emitting parts by varying stack structures in light emitting devices that emit light of different colors.

Additional advantages and features of the disclosure will be set forth in part in the description which follows and in part will become apparent to those having ordinary skill in the art upon examination of the following or may be learned from practice of the disclosure. The features and other advantages of the disclosure may be realized and attained by the structure particularly pointed out in the written description and claims hereof as well as the appended drawings.

To achieve these features and other advantages and in accordance with the purpose of the disclosure, as embodied and broadly described herein, a light emitting display device includes a substrate on which first, second and third sub-pixels are provided, and a first light emitting device, a second light emitting device and a third light emitting device that are respectively provided in the first sub-pixel, the second sub-pixel, and the third sub-pixel to emit light of different wavelengths. Further, the first light emitting device, the second light emitting device and the third light emitting device each includes a first intermediate layer, a second intermediate layer and a third intermediate layer between a first electrode and a second electrode that face each other, respectively, and each of the first intermediate layer, the second intermediate layer and the third intermediate layer includes a red light emitting layer, a green light emitting layer, and a blue light emitting layer in order on the first electrode. Here, the blue light emitting layer of the first intermediate layer may have a vertical phase higher than those of the blue light emitting layers of the second intermediate layer and the third intermediate layer.

It is to be understood that both the foregoing general description and the following detailed description of the present disclosure are examples and explanatory and are intended to provide further explanation of the disclosure as claimed.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a block diagram schematically showing a light emitting display device according to an embodiment of the present disclosure;

FIG. 2 is a plan view showing a light emitting display device according to an embodiment of the present disclosure;

FIG. 3 is a sectional view taken along line I-I′ in FIG. 2;

FIG. 4 is a cross-sectional view respectively showing a blue light emitting device, a green light emitting device, and a red light emitting device for a blue sub-pixel, a green sub-pixel, and a red sub-pixel in FIG. 2;

FIG. 5 shows energy band diagrams of intermediate layers in the blue light emitting device, the green light emitting device, and the red light emitting device in FIG. 4;

FIG. 6 are contour map diagrams showing cavity simulation efficiency of a light emitting display device according to an embodiment of the present disclosure;

FIG. 7 is a cross-sectional view showing a second experimental example to be compared with the first experimental example shown in FIG. 4;

FIGS. 8A and 8B are graphs showing red spectra according to viewing angles of the first experimental example and the second experimental example;

FIGS. 9A and 9B are graphs showing green spectra according to viewing angles of the first experimental example and the second experimental example;

FIG. 10 is a cross-sectional view showing a light emitting device for each sub-pixel of a light emitting display device according to another embodiment of the present disclosure; and

FIG. 11 is a cross-sectional view showing a light emitting display device including the light emitting device shown in FIG. 10.

### DETAILED DESCRIPTION

Reference will now be made in detail to the preferred embodiments of the present disclosure, examples of which are illustrated in the accompanying drawings. Wherever possible, the same reference numbers will be used throughout the drawings to refer to the same or like parts. In the following description of the present disclosure, detailed descriptions of known functions and configurations incorporated herein will be omitted when the same may obscure the subject matter of the present disclosure. In addition, the names of elements used in the following description are selected in consideration of clear description of the specification, and may differ from the names of elements of actual products. The embodiments bring about the complete disclosure of the present disclosure and are only provided to make those skilled in the art understand the scope of the present disclosure.

The shape, size, ratio, angle, number, and the like shown in the drawings to illustrate various embodiments of the present disclosure are merely provided for illustration, and are not limited to the content shown in the drawings. Wherever possible, the same reference numbers will be used throughout the drawings to refer to the same or like parts. In the following description, detailed descriptions of technologies or configurations related to the present disclosure may be omitted so as to avoid unnecessarily obscuring the subject matter of the present disclosure. When terms such as “include,” “have,” “comprise,” “contain,” “constitute,” “make up of,” “formed of,” and “consist of” are used throughout the specification, an additional component may be present, unless the term such as “only” is used. A component described in a singular form encompasses a plurality thereof unless particularly stated otherwise.

The components included in the embodiments of the present disclosure should be interpreted to include an error range or tolerance range, even if there is no additional particular description thereof.

In describing a variety of embodiments of the present disclosure, when terms for positional relationships such as “on,” “above,” “over”, “below”, “under”, “beside”, “beneath”, “near”, “close to,” “adjacent to”, “on a side of”, “next” or the like, are used, at least one intervening element may be present between two elements, unless the term such as “immediately” or “directly” is used.

Spatially relative terms, such as “under,” “below,” “beneath”, “lower,” “over,” “upper” and the like, may be used herein for ease of description to describe one element or feature's relationship to another element(s) or feature(s) as illustrated in the figures. It will be understood that the spatially relative terms can encompass different orientations of an element in use or operation in addition to the orientation depicted in the figures. For example, if an element in the figures is inverted, elements described as “below” or “beneath” other elements or features would then be oriented “over” the other elements or features. Thus, the exemplary term “below” can encompass both an orientation of below and above. Similarly, the exemplary term “above” or “over” can encompass both an orientation of “above” and “below”.

In describing a variety of embodiments of the present disclosure, when terms related to temporal relationships, such as “after,” “subsequently,” “following”, “next”, “before,” and the like, are used, the non-continuous case may be included, unless the term such as “immediately”, “just” or “directly” is used.

In describing a variety of embodiments of the present disclosure, terms such as “first”, “second”, “A”, “B”, “(a)”, “(b)” or the like may be used to describe a variety of components, but these terms only aim to distinguish the same or similar components from one another. Accordingly, throughout the specification, a “first” component may be the same as a “second” component within the technical concept of the present disclosure, unless specifically mentioned otherwise.

In addition, terms, such as first, second, A, B, (a), (b), or the like may be used herein when describing components of the present disclosure. Each of these terminologies is not used to define an essence, order, or sequence of a corresponding component but used merely to distinguish the corresponding component from other components. In the case that it is described that a certain structural element or layer is “connected”, “coupled”, “adhered” or “joined” to another structural element or layer, it is typically interpreted that another structural element or layer may be “connected”, “coupled”, “adhered” or “joined” to the structural element or layer directly or indirectly.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

A term “device” used herein may refer to a display device including a display panel and a driver for driving the display panel. Examples of the display device may include a light-emitting device, and the like. In addition, examples of the device may include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including the light-emitting device and the like, but embodiments of the present disclosure are not limited thereto.

A size and a thickness of each component illustrated in the drawing are illustrated for convenience of description, and the present disclosure is not limited to the size and the thickness of the component illustrated.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein.

In the aspects of the present disclosure, a source electrode and a drain electrode are distinguished from each other, for convenience of description. However, the source electrode and the drain electrode are used interchangeably. The source electrode may be the drain electrode, and the drain electrode may be the source electrode. Also, the source electrode in any one aspect of the present disclosure may be the drain electrode in another aspect of the present disclosure, and the drain electrode in any one aspect of the present disclosure may be the source electrode in another aspect of the present disclosure.

Features of various embodiments of the present disclosure may be partially or completely coupled to or combined with each other, and may be variously inter-operated with each other and driven technically. The embodiments of the present disclosure may be carried out independently from each other, or may be carried out together in an interrelated manner.

As used herein, the term “doped” means that, in a material that occupies most of the weight ratio of a layer, a material (for example, N-type and P-type materials, or organic and inorganic substances) having physical properties different from the material that occupies most of the weight ratio of the layer is added in an amount of less than 30% by weight. In other words, the “doped” layer refers to a layer that is used to distinguish a host material from a dopant material of a certain layer, in consideration of the specific gravity of the weight ratio. Also, the term “undoped” refers to any case other than a “doped” case. For example, when a layer contains a single material or a mixture of materials having the same properties as each other, the layer is included in the “undoped” layer. For example, if at least one of the materials constituting a certain layer is p-type and not all materials constituting the layer are n-type, the layer is included in the “undoped” layer. For example, if at least one of materials constituting a layer is an organic material and not all materials constituting the layer are inorganic materials, the layer is included in the “undoped” layer. For example, when all materials constituting a certain layer are organic materials, at least one of the materials constituting the layer is n-type and the other is p-type, when the n-type material is present in an amount of less than 30 wt %, or when the p-type material is present in an amount of less than 30 wt %, the layer is considered a “doped” layer.

Meanwhile, in this specification, an electroluminescence (EL) spectrum is calculated via the product of (1) a photoluminescence (PL) spectrum that represents unique properties of an emissive material such as a dopant or host material included in an organic emissive layer and (2) an outcoupling emittance spectrum curve determined depending on the structure and optical properties of an organic light-emitting device including thicknesses of organic layers such as an electron transport layer.

Hereinafter, a light emitting display device of the present specification will be described with reference to the drawings.

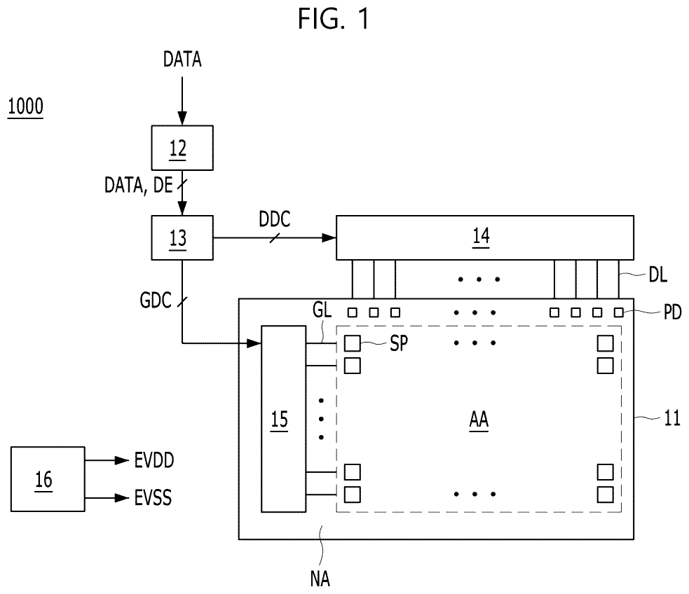

FIG. 1 is a block diagram schematically showing a light emitting display device according to an embodiment of the present disclosure.

As shown in FIG. 1, a light emitting display device 1000 according to an embodiment of the present disclosure may include a display panel 11, an image processor 12, a timing controller 13, a data driver 14, a scan driver 15, and a power supply 16.

The display panel 11 may display an image in response to a data signal DATA supplied from the data driver 14, a scan signal supplied from the scan driver 15, and power supplied from the power supply 16.

The display panel 11 may include a sub-pixel SP disposed in each area of overlap of a plurality of gate lines GL and a plurality of data lines DL. The structure of the sub-pixel SP may be variously changed according to the type of the light emitting display device 1000.

For example, the sub-pixels SP may be formed in a top emission method, a bottom emission method, or a dual emission method, depending on the structure. The sub-pixels SP refer to units capable of emitting light of their own color with or without a specific type of color filter. For example, the sub-pixels SP may include a red sub-pixel, a green sub-pixel, and a blue sub-pixel. Alternatively, the sub-pixels SP may include, for example, a red sub-pixel, a blue sub-pixel, a white sub-pixel, and a green sub-pixel. The sub-pixels SP may have one or more different light emitting areas according to light emitting characteristics. For example, a sub-pixel that emits light of a color different from that of a blue sub-pixel may have a different light emitting area from that of the blue sub-pixel. For example, the red sub-pixel, the blue sub-pixel, and the green sub-pixel, or the red sub-pixel, the blue sub-pixel, the white sub-pixel, and the green sub-pixel may each has a different light-emitting area.

One or more sub-pixels SP may form one unit-pixel. For example, one unit-pixel may include red, green, and blue sub-pixels, in which the red, green, and blue sub-pixels may be disposed in a repeated manner. Alternatively, one unit-pixel may include red, green, blue, and white sub-pixels, in which the red, green, blue, and white sub-pixels may be disposed in a repeated manner, or the red, green, blue, and white sub-pixels may be disposed in a quad type. For example, the red sub pixel, the blue sub pixel, and the green sub pixel may be sequentially disposed along a row direction, or the red sub pixel, the blue sub pixel, and the green sub pixel and the white sub pixel may be sequentially disposed along the row direction. However, the example embodiment of the present disclosure, the color type, disposition type, and disposition order of the sub-pixels are not limiting, and may be configured in various forms according to light emitting characteristics, device lifespans, and device specifications.

The display panel 11 may include a display area AA (inside a dashed line) in which the sub-pixels SP are disposed to display an image and a non-display area NA outside the display area AA and in the vicinity of the display area AA or surrounding the display area AA. The scan driver 15 may be mounted in the non-display area NA of the display panel 11. In addition, the non-display area NA may include a pad including a pad electrode PD.

Here, the display area AA is also referred to as an active area, and the non-display area NA is also referred to as a non-active area.

The image processor 12 may output a data signal DATA supplied from the outside, a data enable signal DE, and the like. The image processor 12 may output one or more of a vertical sync signal, a horizontal sync signal, and a clock signal in addition to the data enable signal DE, but these signals are not shown for convenience of description.

The timing controller 13 may receive a driving signal and the data signal DATA from the image processor 12. The driving signal may include the data enable signal DE. Alternatively, the driving signal may include the vertical sync signal, the horizontal sync signal, and the clock signal. The timing controller 13 may output a data timing control signal DDC for controlling an operation timing of the data driver 14 and a gate timing control signal GDC for controlling an operation timing of the scan driver 15 on the basis of the driving signal.

The data driver 14 may sample and latch the data signal DATA supplied from the timing controller 13 in response to the data timing control signal DDC supplied from the timing controller 13, convert the result into a gamma reference voltage, and output the gamma reference voltage.

The data driver 14 may output the data signal DATA through the data lines DL. The data driver 14 may convert image data into an analog data voltage and supply the analog data voltage to the plurality of data lines DL according to the timing at which the scan signal is applied through the gate lines, when a specific gate line is driven by the scan driver 15. The data driver 14 may be implemented in the form of an integrated circuit (IC). For example, the data driver 14 may be electrically connected to the pad electrode PD disposed in the non-display area NA of the display panel 11 through a flexible circuit film (not shown). Although the data driver 14 is shown as being disposed on one side of the display panel 11 in FIG. 1, the number and position of the data driver 14 are not limited thereto.

The data driver 14 may be mounted by a chip on film (COF), a chip on board (COB), a chip on glass (COG), a tape automated bonding (TAB), or a tape carrier package (TCP) manner, but is not limited thereto.

The scan driver 15 may output a scan signal in response to the gate timing control signal GDC supplied from the timing controller 13. The scan driver 15 may output the scan signal through the gate lines GL, for example, the scan driver 15 may sequentially drive pixel rows in the display area AA by sequentially supplying a scan signal to the plurality of gate lines GL, here, the pixel row may refer to a row including pixels connected to one gate line. The scan driver 15 may sequentially supply a scan signal with an On voltage or an Off voltage to the plurality of gate lines GL. The scan driver 15 may also be referred as gate driver. The scan driver 15 may be implemented in the form of an integrated circuit (IC), or may be implemented in a gate-in-panel (GIP) method in the display panel 11. Alternatively, the scan driver 15 can be implemented by a chip-on-film COF method in which an element is mounted on a film connected to the display panel 11. Or the scan driver 15 may also be disposed in the non-display area NA by a chip on panel (COP), a chip on glass (COG), a tape automated bonding (TAB), or a tape carrier package (TCP), but is not limited thereto.

The power supply 16 may output a high-level voltage and a low-level voltage for driving the display panel 11. The power supply 16 may supply the high-level voltage to the display panel 11 through a first power line EVDD (a driving power line or a pixel power line), and may supply the low-level voltage to the display panel 11 through a second power line EVSS (an auxiliary power line or a common power line).

The display panel 11 is divided into the display area AA and the non-display area NA, and may include the plurality of sub-pixels SP positioned at regions where the gate lines GL and the data lines DL cross each other in a matrix form in the display area AA.

The sub-pixels SP may include sub-pixels that emit at least two of red light, green light, blue light, yellow light, magenta light, or cyan light. Further, the plurality of sub-pixels SP may emit their own colors with or without a specific type of color filter. However, the present disclosure is not limited thereto, and the sub-pixels SP may be configured in various forms depending on the color type, disposition type, disposition order, and the like.

Each sub-pixel SP may include a light emitting part through which light is emitted and a non-light emitting part around the light emitting part.

Hereinafter, a light emitting display device that employs light emitting devices having intermediate layers of which vertical phases are different in adjacent sub-pixels that emit different colors according to an embodiment of the present disclosure will be described with reference to drawings.

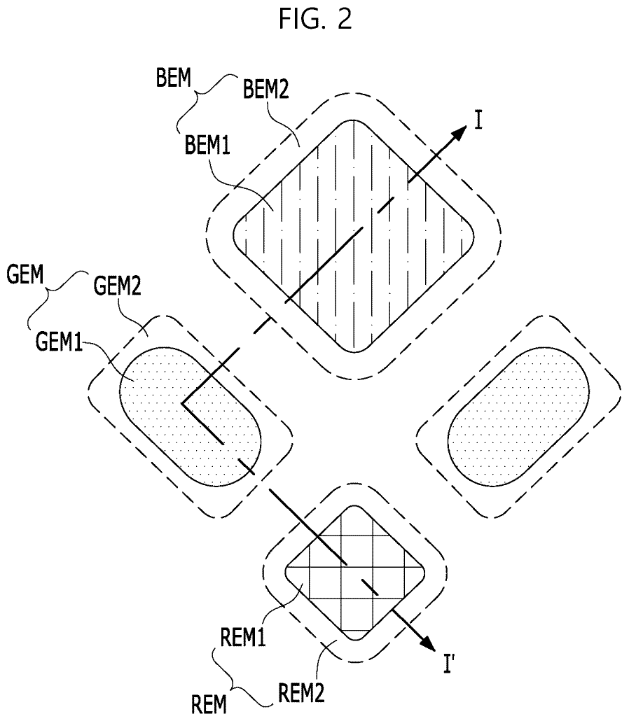

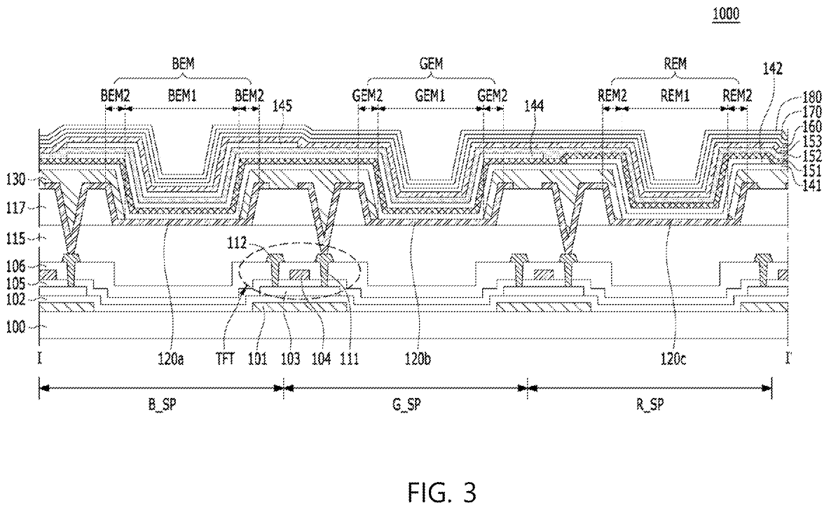

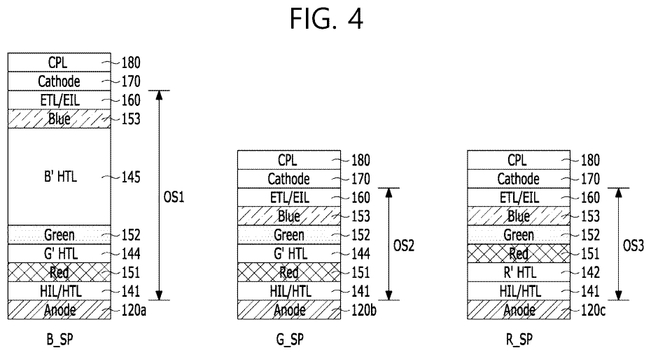

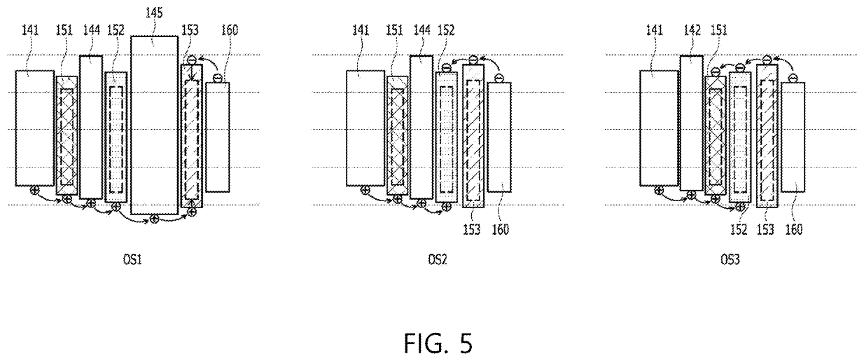

FIG. 2 is a plan view showing a light emitting display device according to an embodiment of the present disclosure, and FIG. 3 is a sectional view taken along line I-I′ in FIG. 2. FIG. 4 is a cross-sectional view respectively showing a blue light emitting device, a green light emitting device, and a red light emitting device for a blue sub-pixel, a green sub-pixel, and a red sub-pixel in FIG. 2. FIG. 5 shows energy band diagrams of intermediate layers in the blue light emitting device, the green light emitting device, and the red light emitting device in FIG. 4.

As shown in FIG. 3, the light emitting display device 1000 according to the embodiment of the present disclosure includes a substrate 100 on which first to third sub-pixels B_SP, G_SP, and R_SP are provided.

Further, as shown in FIGS. 2 and 3, the light emitting display device according to the embodiment of the present disclosure includes a first light emitting device BEM that emits light of a first wavelength in the first sub-pixel B_SP, a second light emitting device GEM that emits light of a second wavelength longer than the first wavelength in the second sub-pixel G_SP, and a third light emitting device REM that emits light of a third wavelength longer than the second wavelength in the third sub-pixel R_SP.

For example, the light of the first wavelength may be light of a blue wavelength. The light of the blue wavelength emitted from the first light emitting device BEM may have an emission peak at 420 nm to 490 nm.

For example, the light of the second wavelength may be light of a green wavelength. The light of the green wavelength emitted from the second light emitting device GEM may have an emission peak at 500 nm to 590 nm.

For example, the light of the third wavelength may be light of a red wavelength. The light of the red wavelength emitted from the third light emitting device REM may have an emission peak at 600 nm to 650 nm.

The first to third light emitting devices (BEM, GEM, and REM) respectively include first light emitting parts (BEM1, GEM1, and REM1) which may be exposed parts of a bank 130, and second light emitting parts (BEM2, GEM2, and REM2) that surround or are adjacent to the first light emitting parts (BEM1, GEM1, and REM1) and overlap the bank 130.

The light emitting display device of the present disclosure includes the second light emitting parts (BEM2, GEM2, and REM2) that overlap the bank 130, so that the light emitting area can be expanded from the side of the first light emitting parts (BEM1, GEM1, and REM1), thereby making it possible to expand a light emitting area in the entire substrate 100 to achieve high resolution.

Further, the first light emitting device BEM, the second light emitting device GEM, and the third light emitting device REM include a first intermediate layer OS1, a second intermediate layer OS2, and a third intermediate layer OS3 between first electrodes (120a, 120b, 120c) and a second electrode 170 that face each other, respectively, as shown is FIG. 4. In each light emitting device, the first electrodes (120a, 120b, and 120c) function as anodes, and the second electrode 170 functions as a cathode. In addition, according to a patterned state, the first electrodes (120a, 120b, and 120c) are also referred to as pixel electrodes, and the second electrode 170 is also referred to as a common electrode.

In the light emitting display device according to the embodiment of the present disclosure, the first electrodes (120a, 120b, and 120c) may include reflective electrodes, and the second electrode 170 may be a transflective electrode or a transparent electrode. A capping layer 180 may be further provided on the second electrode 170 to protect the first, second and third light emitting devices (BEM, GEM, and REM), respectively, and to increase the emission efficiency of light emitted from the second electrode 170. The capping layer 180 may include at least one of an organic capping layer or an inorganic capping layer. The capping layer 180 may be formed by stacking a plurality of capping layers having different refractive indices to maximize or increase the emission effect.

In a case where the light emitting device employs a top emission type, the first electrodes (120a, 120b, and 120c) may include reflective electrodes, and the second electrode (cathode) 170 may include a transparent electrode or a transflective electrode. For example, in a case where the first electrodes (120a, 120b, and 120c) include reflective electrodes, the first electrodes (120a, 120b, and 120c) may have a multilayer structure including a transparent conductive layer and an opaque conductive layer having high reflective efficiency. The transparent conductive layer of the first electrodes (120a, 120b, and 120c) may be made of a material having a relatively large work function value such as indium tin oxide (ITO) or indium zinc oxide (IZO), and the opaque conductive layer may be formed of a material selected from a group consisting of silver (Ag), magnesium (Mg), aluminum (Al), copper (Cu), molybdenum (Mo), titanium (Ti), nickel (Ni), chromium (Cr), or tungsten (W) or an alloy thereof, as a single layer or multiple layers. For example, the first electrodes (120a, 120b, and 120c) may have a structure in which a transparent conductive layer, an opaque conductive layer, and a transparent conductive layer are sequentially stacked, or a structure in which a transparent conductive layer and an opaque conductive layer are sequentially stacked. For example, the first electrodes (120a, 120b, and 120c) may include a stacked structure of ITO/APC(Ag—Pd—Cu)/ITO. However, the present disclosure is not limited thereto.

For example, the second electrode 170 may be made of a transparent conductive material such as indium tin oxide (ITO) or indium zinc oxide (IZO), or may be made of silver (Ag), aluminum (Al), magnesium (Mg), calcium (Ca), ytterbium (Yb), or an alloy including at least one thereof, having a thickness thin enough to transmit light. In a case where the second electrode 170 is made of metal or metal alloy having a thickness thin enough to transmit light, the second electrode 170 has a transflective property, so that light resonated in the intermediate layers (OS1, OS2, and OS3) between the first electrodes (120a, 120b, and 120c) and the second electrode 170 has a strong cavity characteristic and can pass through the second electrode 170.

Further, the first electrodes (120a, 120b, and 120c) of the first light emitting device BEM, the second light emitting device GEM, and the third light emitting device REM may respectively include a first area provided on an upper surface of a first planarization layer 115 and a second area provided on a second planarization layer 117 having a side slope outside the first area. The first area corresponds to each of the first light emitting parts (BEM1, GEM1, and REM1) in FIG. 2, and the second area corresponds to each of the second light emitting parts (BEM2, GEM2, and REM2) in FIG. 2. The second area is disposed at an overlapped region between the first electrodes (120a, 120b, and 120c) and the bank 130. The second area is exposed by the second planarization layer 117 and covered by the bank 130, the second area functions as another emitting parts beside the first area. Since the second planarization layer 117 further defines another emitting parts, the second planarization layer 117 can be called as an emission extension defining layer.

The second area of the first electrodes (120a, 120b, and 120c) positioned in the second light emitting parts (BEM2, GEM2, and REM2) is positioned on the side slope of the second planarization layer 117. Accordingly, since light generated in the intermediate layers (OS1, OS2, and OS3) between the first electrodes (120a, 120b, and 120c) and the second electrode 170 is reflected from the second area of the first electrodes (120a, 120b, and 120c) on the side slope of the second planarization layer 117, the second area of the first electrodes (120a, 120b, and 120c) may be considered as a side mirror. The light emitting display device according to the present disclosure has an advantage in that the light emission effect is improved by the reflection effect by the side mirror and light emission is generated even in an area that overlaps the bank 130, thereby making it possible to increase the resolution.

The bank 130 is formed to expose the first area of the first electrodes (120a, 120b, and 120c) and cover the second planarization layer 117 and the second area of the first electrodes (120a, 120b, and 120c) on the second planarization layer 117.

The emission extension defining layer 117 is positioned on the first planarization layer 115, and each of the first electrodes (120a, 120b, and 120c) may be connected to a thin film transistor (TFT) under the first planarization layer 115 through a contact hole formed to penetrate the second planarization layer 117 and the first planarization layer 115. The second planarization layer 117 may be referred to as a second planarization layer 117 or simply as the second planarization layer 117. It should be understood that “defining layer” does not require that the second area is only present or completely present on the defining layer. For example, the second area of the first electrodes (120a, 120b, and 120c) may overlap the second planarization layer 117 partially or fully and may extend somewhat beyond either edge of the side slope of the second planarization layer 117.

The substrate 100 may be formed of at least one of glass, a plastic film, a flexible polymer film or a metallic film. For example, the flexible polymer film may be made of any one of polyimide (PI), polyethylene terephthalate (PET), acrylonitrile-butadiene-styrene copolymer(ABS), polymethyl methacrylate(PMMA), polyethylene naphthalate (PEN), polycarbonate (PC), polyethersulfone (PES), polyarylate (PAR), polysulfone (PSF), cyclic olefin copolymer(COC), triacetylcellulose(TAC), polyvinyl alcohol(PVA), and polystyrene(PS), and the present disclosure is not limited thereto.

On the substrate 100, a thin film transistor (TFT) including a gate electrode 104, a semiconductor layer 103 with a gate insulating layer 105 interposed between the semiconductor layer 103 and the gate electrode 104, and a source electrode 112 and a drain electrode 111 connected to both sides of the semiconductor layer 103 is provided. A channel region of the semiconductor layer 103 may be provided with a channel protecting layer when beneficial.

One of the source electrode 112 and the drain electrode 111 may be connected to each of the first electrodes (120a, 120b, and 120c) of the first to third light emitting devices.

The semiconductor layer 103 may be formed of, for example, at least one of oxide semiconductor material, an amorphous semiconductor material, a polycrystalline semiconductor material.

The oxide semiconductor material may have an excellent effect of preventing a leakage current and relatively inexpensive manufacturing cost. The oxide semiconductor may be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor may be made of polycrystalline silicon (poly-Si), but is not limited thereto.

The amorphous semiconductor material may be made of amorphous silicon (a-Si), but is not limited thereto.

The organic semiconductor material may include metal-organic compounds, but is not limited thereto.

An illustrated example of the thin film transistor (TFT) shows a top gate type structure in which the gate electrode 104 is provided above the semiconductor layer 103. The light emitting display device of the present disclosure is not limited thereto, and a bottom gate type structure or a dual gate type structure may be applied. In the bottom gate type structure, the gate electrode of the transistor is disposed under the semiconductor layer 103 of the transistor. In the dual gate type structure, the gate electrodes of the transistor are disposed over and under the semiconductor layer 103 of the transistor respectively.

For example, when a switching transistor is configured to have a dual gate type structure, channel mobility may be increased, more current may flow, and stability of the transistor can be improved by protecting the semiconductor layer 103 from external light.

In addition, at least on a lower side of the channel region of the semiconductor layer 103, a light blocking layer 101 for preventing an abnormal operation of the semiconductor layer 103 due to light coming from the lower side of the substrate 100 may be further provided.

A buffer layer 102 may be provided between the light blocking layer 101 and the semiconductor layer 103.

In the illustrated example, one thin film transistor TFT is provided for each sub-pixel, but the present disclosure is not limited thereto, and two or more thin film transistors TFTs and one or more capacitors may be further provided for each sub-pixel, when beneficial. For example, the sub-pixel of the present disclosure may have a 2T1C pixel circuit including two TFTs and one capacitor, a 3T1C pixel circuit including three TFTs and one capacitor, a 3T2C pixel circuit including three TFTs and two capacitors, a 5T1C pixel circuit including five TFTs and one capacitor, a 5T2C pixel circuit including five TFTs and two capacitors, a 7T2C pixel circuit including seven TFTs and two capacitors, or the like. In a case where a plurality of thin film transistors is provided in each sub-pixel, the plurality of thin film transistors may be provided as different types of thin film transistors having different stacked structures or including different types of semiconductor layers.

An interlayer insulating layer 106 may be further provided between the gate electrode 104 and the source/drain electrodes 112 and 111. In some cases, the gate electrode 104, and the source electrode 112 and the drain electrode 111 may be provided on the same layer. In this case, the interlayer insulating layer may be omitted. The present disclosure is not limited to a specific structure.

The first planarization layer 115 may be provided to protect the thin film transistor TFT. Additionally, an inorganic protecting film may be further provided between the thin film transistor TFT and the first planarization layer 115.

The buffer layer 102, the gate insulating layer 105, the interlayer insulating layer 106, the first planarization layer 115, the second planarization layer 117, and the bank 130 provided on the substrate 100 are provided as an insulating layer, respectively.

The buffer layer 102, the gate insulating layer 105, the interlayer insulating layer 106, and the inorganic protecting film may be formed of an inorganic insulating layer or an inorganic insulating film, for example, at least one of a nitride film, an oxide film, and an oxynitride film. These films may be provided as a single film or multiple films, respectively. For example, the inorganic insulating film in a single layer may be a silicon oxide (SiO_{X}) film, a silicon nitride (SiN_{X}) film or a silicon oxynitride (SiON) film, and inorganic insulating films in multiple layers may formed by alternately stacking two or more among one or more silicon oxide (SiO_{X}) films, one or more silicon nitride (SiN_{X}) films, and one or more silicon oxynitride (SiON) films, and one or more amorphous silicon (a-Si), but the present disclosure is not limited thereto.

In addition, the first planarization layer 115, the second planarization layer 117, and the bank 130 may be formed of, for example, at least one of organic materials of photo acryl, polyimide, benzocyclobutene resin, or acrylate.

Among the components formed on the substrate 100, the components up to the lower surface of each of the first electrodes (120a, 120b, and 120c) of the light emitting device are referred to as a thin film transistor array.

As shown in FIGS. 3 and 4, the first intermediate layer, the second intermediate layer, and the third intermediate layer include a red light emitting layer 151, a green light emitting layer 152, and a blue light emitting layer 153 close to the first electrodes (120a, 120b, and 120c).

More specifically, the first intermediate layer OS1 of the first light emitting device BEM includes a hole injection and transport part 141 in which a hole injection layer (HIL) and a hole transport layer (HTL) are sequentially stacked, the red light emitting layer 151, a second compensation layer 144, the green light emitting layer 152, a first compensation layer 145, the blue light emitting layer 153, and an electron transport and injection part 160 in which an electron transport layer (ETL) and an electron injection layer (EIL) are sequentially stacked, on the first electrode 120a.

Further, the second intermediate layer OS2 of the second light emitting device GEM includes the hole injection and transport part 141, the red light emitting layer 151, the second compensation layer 144, the green light emitting layer 152, the blue light emitting layer 153, and the electron transport and injection part 160, on the first electrode 120b.

In addition, the third intermediate layer OS3 of the third light emitting device REM includes the hole injection and transport part 141, the third compensation layer 142, the red light emitting layer 151, the green light emitting layer 152, and the blue light emitting layer 153, and the electron transport and injection part 160, on the first electrode 120c.

In the light emitting display device of the present disclosure, it is characterized in that the blue light emitting layer 153 in the first intermediate layer OS1 of the first light emitting device BEM has a vertical phase higher than those of the blue light emitting layers 153 in the second intermediate layer OS2 of the second light emitting device GEM and the third intermediate layer OS3 of the third light emitting device REM.

Particularly, the first compensation layer 145 provided only in the first light emitting device BEM has a greater thickness than those of the second compensation layer 144 and the third compensation layer 142 of the second and third light emitting devices GEM and REM, and functions to adjust the vertical phase so that the blue light emitting layer 153 in the first light emitting device BEM can emit light at an anti-node in an order different from those of the green light emitting layer 152 and the red light emitting layer 151 in the second and third light emitting devices GEM and REM.

Here, the “anti-node” refers to an area between the first electrodes (120a, 120b, and 120c) and the second electrode 170 (cathode) where the maximum amplitude of the light emitting layer is generated.

The second compensation layer 144 may be further provided in the first light emitting device BEM to increase the vertical phase of the blue light emitting layer 153 in the first light emitting device BEM. However, the present disclosure is not limited thereto, and the second compensation layer 144 may be not provided in the first light emitting device BEM.

The first, second and third compensation layers (145, 144, and 142) may be optical compensation layers in that they optically select a vertical phase of each light emitting device. Further, the first to third compensation layers (145, 144, and 142) may be formed of a hole transport material, or may be formed of the same material as a host included in the blue light emitting layer 153, the green light emitting layer 152, and the red light emitting layer 151 that are adjacent to each other in each light emitting device.

The blue light emitting layer 153 includes at least one host, and a blue dopant that generates excitons and uses the excitons for light emission.

The green emission layer 152 includes at least one host, and a green dopant that generates excitons and uses the excitons for emission.

The red light emitting layer 151 includes one host, and a red dopant that generates excitons and uses the excitons for light emission.

As shown in FIG. 4, in the light emitting display device of the present disclosure, the red light emitting layer 151 is disposed closest to the first electrodes (120a, 120b, and 120c), and then the green light emitting layer 152 is disposed next, in each light emitting device. Next, the blue light emitting layer 153 is disposed. That is, among the light emitting layers, the red light emitting layer 151 having the lowest turn-on voltage is disposed at the lowermost side, and the blue light emitting layer 153 having the highest turn-on voltage is disposed at the uppermost side.

From the viewpoint of an energy band gap, as shown in FIG. 5, the energy band gap of each host increases in the order of the red light emitting layer 151, the green light emitting layer 152, and the blue light emitting layer 153.

For example, as shown in FIG. 5, in a case where a turn-on voltage for turning on the red light emitting layer 151 is applied in the third light emitting device REM that emits red light, holes from the first electrode 120c and electrons from the second electrode 170 are transferred to the red light emitting layer 151, so that the red light emitting layer 151 emits red light. Here, since the voltage applied between the first electrode 120c and the second electrode 170 has a voltage level lower than a turn-on voltage for each of the green light emitting layer 152 and the blue light emitting layer 153, the electrons may pass through the green light emitting layer 152 and the blue light emitting layer 153 without being used for light emission to be transferred to the red light emitting layer 151.

On the other hand, the first compensation layer 142 below the red light emitting layer 151 does not only select the vertical phase of the red light emitting layer 151, but also functions as an electron blocking layer that prevents the electrons transferred to the red light emitting layer 151 and excitons formed by combining the electrons and holes from escaping from the red light emitting layer 151.

As shown in FIG. 5, in a case where a turn-on voltage for turning on the green light emitting layer 152 is applied in the second light emitting device GEM that emits green light, holes from the first electrode 120b and electrons from the second electrode 170 are transferred to the green light emitting layer 152, so that the green light emitting layer 152 emits green light. Here, since the voltage applied between the first electrode 120b and the second electrode 170 has a voltage level lower than a turn-on voltage for the blue light emitting layer 153, the electrons may pass through the blue light emitting layer 153 to be transferred to the green light emitting layer 152, may meet the holes transferred from the first electrode 120b to form excitons, and may be used for light emission. On the other hand, the second compensation layer 144 below the green light emitting layer 152 not only selects the vertical phase of the green light emitting layer 152, but also functions as an electron blocking layer that prevents the electrons transferred to the green light emitting layer 152 and excitons formed by combining the electrons and holes from escaping from the green light emitting layer 152. In the second light emitting device GEM, the electrons are first used for excitons in the green light emitting layer 152 before reaching the red light emitting layer 151, and the holes are not transferred downwards, so that the red light emitting layer 151 may be used as a hole delivery route.

As shown in FIG. 5, in a case where a turn-on voltage for turning on the blue light emitting layer 153 is applied in the first light emitting device BEM that emits blue light, holes from the first electrode 120a and electrons from the second electrode 170 are transferred to the blue light emitting layer 153, so that the blue light emitting layer 153 finally emits light. Here, the voltage applied between the first electrode 120a and the second electrode 170 is a driving voltage high enough to turn on the blue light emitting layer 153, and the electrons preferentially meet the holes in the blue light emitting layer 153 and are used for forming excitons, and thus, there is no loss of excitons to the other light emitting layers 152 and 151. Here, the first compensation layer 145 below the blue light emitting layer 153 not only selects the vertical phase for light emission of the blue light emitting layer 153, but also functions as an electron blocking layer that prevents the electrons and excitons from escaping downwards and confines carriers into the blue light emitting layer 153.

That is, in the light emitting display device of the present disclosure, since the red light emitting layer 151, the green light emitting layer 152, and the blue light emitting layer 153 are sequentially disposed on the first electrodes (120a, 120b, and 120c), and their energy band gaps are set in the order of the blue light emitting layer 153>the green light emitting layer 152>the red light emitting layer 151, when the maximum turn-on voltage is applied, excitons are generated in the blue light emitting layer 153 to be wholly used for the blue light emitting layer 153. Since the green light emitting layer 152 and the red light emitting layer 151 also have different turn-on voltages, in a case where excitons are primarily used for the light emitting layer having a higher turn-on voltage, the light emitting layer having a lower turn-on voltage does not emit light.

Further, in the light emitting display device of the present disclosure, even in a case where light is emitted from the second light emitting units (BEM2, GEM2, and REM2) that overlap the bank 130, there are differences in vertical phases between the intermediate layers due to the large thickness of the first compensation layer 145, which lengthening a physical distance on the side between adjacent light emitting parts, thereby limiting side leakage current. In the prior-art light emitting display devices, especially, in low grayscale blue driving, there is a problem in that adjacent red light emission or green light emission occurs. However, according to the light emitting display device of the present disclosure, as shown in FIG. 4, since the vertical distance difference between the blue light emitting layer 153 where light is emitted in the first light emitting device BEM and the green light emitting layer 152 in the second light emitting device GEM and the red light emitting layer 151 in the third light emitting device REM is large, the vertical distance between the light emitting layers in which light is emitted between adjacent light emitting parts is large, and thus, it is possible to prevent mixed color light emission due to side leakage current.

Further, even in a case where light is directed from the second light emitting parts (BEM2, GEM2, and REM2) to the adjacent light emitting part due to the energy band gap difference between the light emitting layers used in each light emitting device shown in FIG. 5, energy re-absorption does not occur by the adjacent light emitting part due to the energy band gap difference, so that photons are not generated due to mixed color light emission, thereby making it possible to prevent mixed color light emission due to side emission by a side mirror from being visually recognized.

As described above, in the light emitting display device of the present disclosure, the blue light emitting layer 153 of the first light emitting device BEM is positioned at the second anti-node, and the green light emitting layer 152 of the second light emitting device GEM and the red light emitting layer 151 of the third light emitting device REM are positioned at the first anti-node, respectively. That is, the light emitting display device of the present disclosure has a configuration in which a position of an anti-node where blue light emission is performed and positions of anti-nodes where green light emission and red light emission are performed are different from each other. This is different from the prior-art structure that uses the same anti-node in using different red, green, and blue light emitting layers in adjacent light emitting devices. This will be described with reference to a contour map.

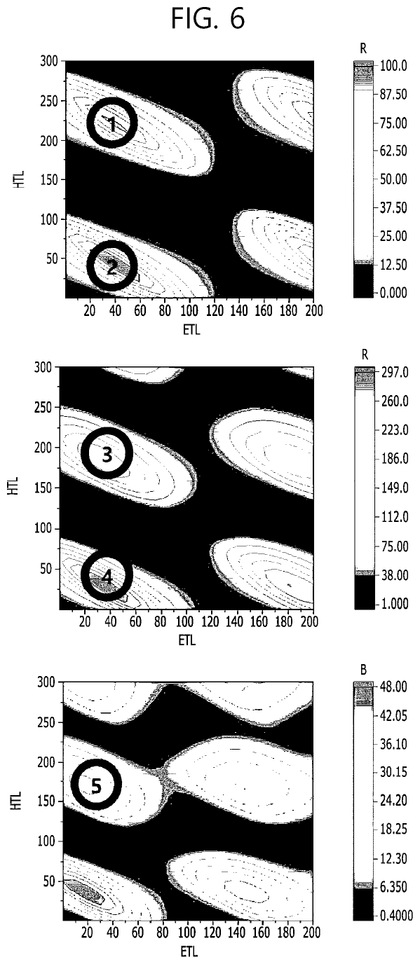

FIG. 6 are contour map diagrams showing cavity simulation efficiency of the light emitting display device according to the embodiment of the present disclosure.

In FIG. 6, a horizontal axis represents a distance from the second electrode 170. Since an electron transport layer is disposed between each light emitting layer and the second electrode 170, the horizontal axis also represents the thickness of the electron transport layer. In FIG. 6, a vertical axis represents a distance from the first electrodes (120a, 120b, and 120c). Since a hole transport layer or an auxiliary layer having a similar function to the hole transport layer is disposed between the first electrodes (120a, 120b, and 120c) and each light emitting layer, the vertical axis also represents the thickness of the hole transport layer.

As shown in FIG. 6, in the light emitting display device of the present disclosure, red light emission occurs at the first anti-node. As shown in the first contour map, light is emitted at a position that is distant from the second electrode 170 by approximately 20 nm to 60 nm and is distant from the first electrode 120c by approximately 25 nm to 80 nm, that is, at position \textcircled{2}. However, the present disclosure is not limited thereto, the red light may be emitted at a position that is distant from the second electrode 170 by approximately 30 nm to 50 nm and is distant from the first electrode 120c by approximately 35 nm to 70 nm.

Further, in the light emitting display device of the present disclosure, green light emission occurs at the first anti-node. As shown in the second contour map, light is emitted at a position that is distant from the second electrode 170 by approximately 20 nm to 60 nm and is distant from the first electrode 120c by approximately 25 nm to 60 nm, that is, at position \textcircled{4}. However, the present disclosure is not limited thereto, the green light may be emitted at a position that is distant from the second electrode 170 by approximately 30 nm to 50 nm and is distant from the first electrode 120c by approximately 35 nm to 50 nm.

In addition, in the light emitting display device of the present disclosure, blue light emission occurs at the second anti-node. As shown in the third contour map, light is emitted at a position that is distant from the second electrode 170 by approximately 20 nm to 60 nm and is distant from the first electrode 120c by approximately 140 nm to 200 nm, that is, at position \textcircled{5}. However, the present disclosure is not limited thereto, the blue light may be emitted at a position that is distant from the second electrode 170 by approximately 30 nm to 50 nm and is distant from the first electrode 120c by approximately 150 nm to 190 nm.

On the other hand, in the prior art structure in which different red, green, and blue light emitting layers are used in adjacent light emitting devices, the same anti-node is used. Here, assuming that each light emitting layer is positioned at the second anti-node, the red light emitting layer is located at position \textcircled{1} in the first contour map, the green light emitting layer is located at position \textcircled{3} in the second contour map, and the blue light emitting layer is located at position \textcircled{5} in the third contour map. In this case, in the prior art structure in which different red, green, and blue light emitting layers are used in the adjacent light emitting devices, the cavity effect decreases in the red light emitting layer and the green light emitting layer.

However, in the light emitting display device of the present disclosure, since the third light emitting device that emits at least red light and the second light emitting device that emits green light use the first anti-node, the cavity effect increases at least in red and green.

Hereinafter, a light emission efficiency according to a viewing angle in the above-described first experimental example of the embodiment of the present disclosure shown in FIGS. 2 to 5 and a light emission efficiency according to a viewing angle in the second experimental example of the prior art structure in which different red, green, and blue light emitting layers are used in adjacent light emitting devices will be described.

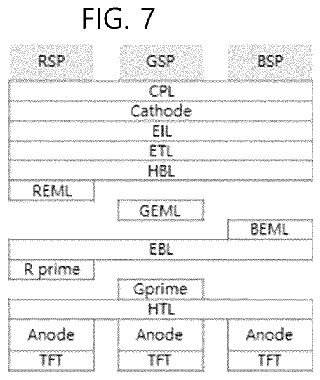

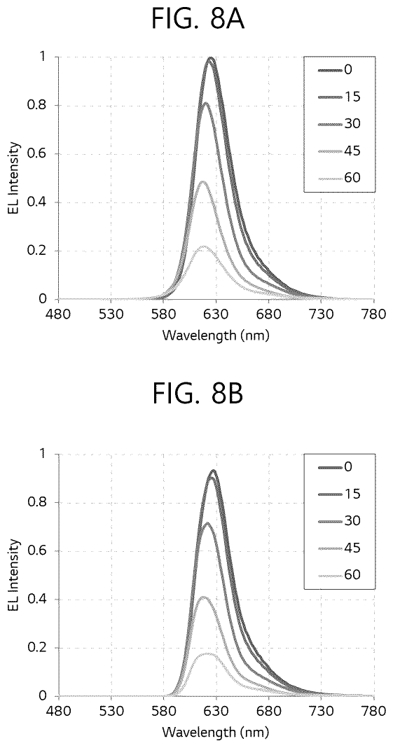

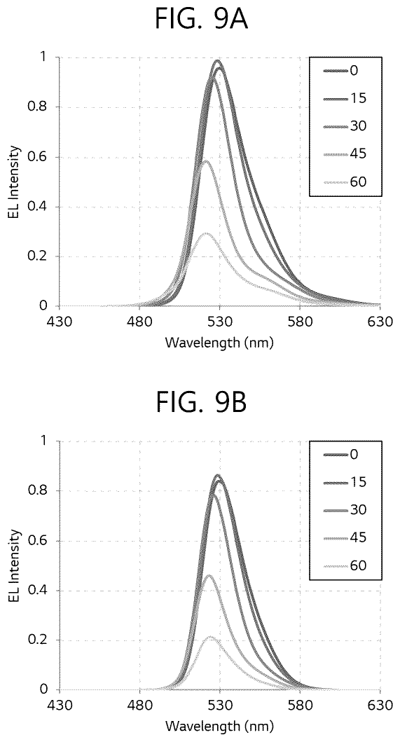

FIG. 7 is a cross-sectional view showing the second experimental example to be compared with the first experimental example shown in FIG. 4. FIGS. 8A and 8B are graphs showing red spectra according to viewing angles of the first experimental example and the second experimental example. FIGS. 9A and 9B are graphs showing green spectra according to viewing angles of the first experimental example and the second experimental example.

As shown in FIG. 7, the light emitting display device used in the second experimental example (Ex2) is configured so that a red light emitting layer REML, a green light emitting layer GEML, and a blue light emitting layer BEML that emit light of different wavelengths are provided in first to third sub-pixels (R_SP, G_SP, and B_SP) to implement a red light emitting device, a green light emitting device, and a blue light emitting device.

Specifically, the red light emitting device is provided with a thin film transistor (TFT), a first electrode (Anode), a hole transport layer (HTL), a first hole transport auxiliary layer (R prime), an electron blocking layer (EBL), a red light emitting layer (REML), a hole blocking layer (HBL), an electron transport layer (ETL), an electron injection layer (EIL), a second electrode (Cathode), and a capping layer (CPL), on a substrate.

The green light emitting device is provided with the thin film transistor (TFT), the first electrode (Anode), the hole transport layer (HTL), a second hole transport auxiliary layer (G prime), the electron blocking layer (EBL), and a green light emitting layer (GEML), the hole blocking layer (HBL), the electron transport layer (ETL), the electron injection layer (EIL), the second electrode (Cathode), and the capping layer (CPL), on the substrate.

The blue light emitting device is provided with the thin film transistor (TFT), the first electrode (Anode), the hole transport layer (HTL), the electron blocking layer (EBL), a blue light emitting layer (BEML), the hole blocking layer (HBL), the electron transport layer (ETL), the electron injection layer (EIL), the second electrode (Cathode), and the capping layer (CPL), on the substrate.

Since the light emitting display device according to the second experimental example (Ex2) may need five or more FMM masks in using the first and second hole transport auxiliary layers (R prime and G prime) together with the red light emitting layer (REML), the green light emitting layer (GEML), and the blue light emitting layer (BEML), the yield may be lowered.

On the other hand, in the light emitting display device of the present disclosure of the first experimental example (Ex1) having the structure of FIG. 4, since the red light emitting layer (REML) 151, the green light emitting layer (GEML) 152, and the blue light emitting layer (BEML) 153 are commonly provided in the red light emitting device, the green light emitting device, and the blue light emitting device, it is possible to use a common mask. That is, it is possible to use the FMM mask only for the first to third compensation layers 145, 144, and 142, thereby reducing the number of FMM masks.

Further, in comparing viewing angle efficiencies of red in the light emitting display devices of the first experimental example (Ex1) having the device structure of FIG. 4 and the second experimental example (Ex2) having the device structure of FIG. 7, as shown in Table 1 and FIGS. 8A and 8B, as the viewing angle increases, the light emitting display device of the first experimental example (Ex1) has a high red efficiency compared with the second experimental example (Ex2). The red luminous efficacy of the light emitting display device of the first experimental example (Ex1) according to the present disclosure may be increased by 117% on average at a viewing angle of 0° to 60°.

TABLE 1

| | Efficiency at red viewing angle | | | | |
|---|---|---|---|---|---|
| | 0° | 15° | 30° | 45° | 60° |
| First | 109% | 110% | 114% | 121% | 131% |
| experimental | | | | | |
| example | | | | | |
| Second | 100% | 100% | 100% | 100% | 100% |
| experimental | | | | | |
| example | | | | | |

Further, in comparing viewing angle efficiencies of green in the light emitting display devices of the first experimental example (Ex1) having the device structure of FIG. 4 and the second experimental example (Ex2) having the device structure of FIG. 7, as shown in Table 1 and FIGS. 9A and 9B, as the viewing angle increases, the light emitting display device of the first experimental example (Ex1) has a high green efficiency compared with the second experimental example (Ex2). The green luminous efficacy of the light emitting display device of the first experimental example (Ex1) according to the present disclosure may be increased by 122% on average at a viewing angle of 0° to 60⁰.

TABLE 2

| | Efficiency at green viewing angle | | | | |
|---|---|---|---|---|---|
| | 0° | 15° | 30° | 45° | 60° |
| First | 109% | 109% | 112% | 126% | 154% |
| experimental | | | | | |
| example | | | | | |
| Second | 100% | 100% | 100% | 100% | 100% |
| experimental | | | | | |
| example | | | | | |

As described above, according to the present disclosure, it is possible to additionally obtain the advantage of increasing the efficiency of red and the efficiency of green according to the viewing angle change.

Further, the light emitting display device of the present disclosure may further include a fourth sub-pixel that expresses white in addition to the above-described first to third sub-pixels. This will be described later with reference to the drawings.

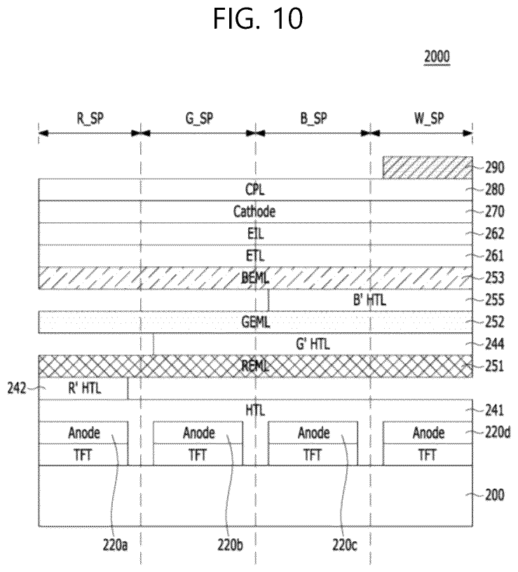

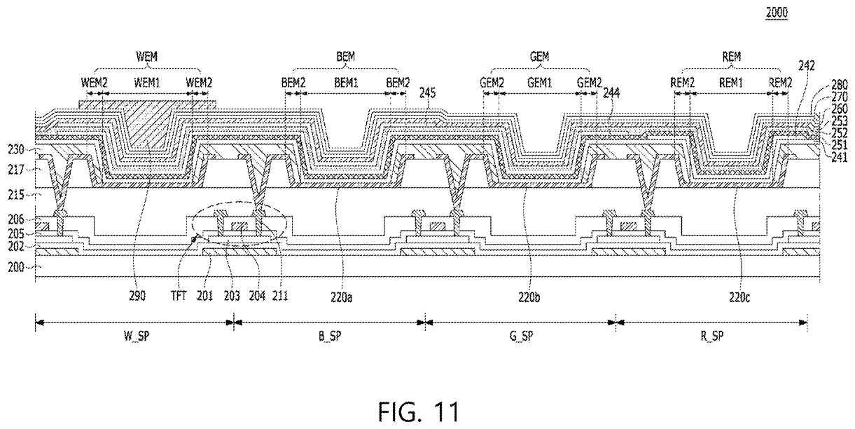

FIG. 10 is a cross-sectional view showing a light emitting device for each sub-pixel of a light emitting display device according to another embodiment of the present disclosure. FIG. 11 is a cross-sectional view showing a light emitting display device including the light emitting device in FIG. 10.

As shown in FIGS. 10 and 11, a light emitting display device 2000 according to another embodiment of the present disclosure includes a substrate 200 on which first to fourth sub-pixels (R_SP, G_SP, B_SP, and W_SP) are provided, and first electrodes (220a, 220b, 220c, and 220d) that are spaced apart from each other in the first to fourth sub-pixels (R_SP, G_SP, B_SP, and W_SP).

Further, the light emitting display device 2000 includes first intermediate layers (241, 251, 244, 252, 255, 253, 261, and 262) that are provided on the first electrodes 220c and 220d, corresponding to the third sub-pixel B_SP and the fourth sub-pixel W_SP.

The light emitting display device 2000 includes second intermediate layers (241, 242, 251, 252, 253, 261, and 262) that are provided on the first electrode 220a, corresponding to the first sub-pixel R_SP.

The light emitting display device 2000 includes third intermediate layers (241, 251, 244, 252, 253, 261, and 262) that are provided on the first electrode 220b, corresponding to the third sub-pixel G_SP.

Further, the light emitting display device 2000 includes a second electrode 270 that is provided on the electron injection layer 262 that is the uppermost layer among the first to third intermediate layers.

The blue light emitting layer 253 at the third and fourth sub-pixels (B_SP and W_SP) may have a vertical phase higher than those of the blue light emitting layers of the adjacent second and third intermediate layers.

The light emitting display device 2000 may further include a color filter 290 on the second electrode 270, corresponding to the fourth sub-pixel W_SP, to change blue light emitted through the second electrode 270 into white light.

More specifically, the second intermediate layer of the first sub-pixel R_SP includes a hole injection and transport unit or layer 241, a third compensation layer 242, a red light emitting layer 251, and a green light emitting layer 252, a blue light emitting layer 253, an electron transport layer 261, and an electron injection layer 262, on a first electrode 220a.

The third intermediate layer OS3 of the second sub-pixel G_SP includes the hole injection and transport part 241 in which the hole injection layer (HIL) and the hole transport layer (HTL) are sequentially stacked, the red light emitting layer 251, the second compensation layer 244, the green light emitting layer 252, the blue light emitting layer 253, the electron transport layer 261, and the electron injection layer 262, on a first electrode 220b.

In the light emitting display device 2000 according to the embodiment of the present disclosure, it is characterized in that the blue light emitting layer 253 in the third sub-pixel B_SP and the fourth sub-pixel W_SP that emit blue and white light has a vertical phase higher than that of the blue light emitting layer 253 in the first and second sub-pixels R_SP and G_SP. This is achieved by making the first compensation layer 255 thicker than each of the second compensation layer 244 and the third compensation layer 242.

Particularly, vertical phases are adjusted so that the blue light emitting layer 253 in the third sub-pixel B_SP that emits blue light and the fourth sub-pixel W_SP that emits white light can emit light at an anti-node in an order different from those of the green light emitting layer 252 and the red light emitting layer 251 in the first and second sub-pixels R_SP and G_SP.

The fourth sub-pixel W_SP emits the same blue light as the third sub-pixel B_SP from the second electrode 270, is provided with the color filter layer 290 that converts blue to white above the second electrode 270, and finally emits white light to the outside to express white color.

The first to third compensation layers (245, 244, and 242) may be optical compensation layers in that they optically select a vertical phase of each light emitting device. Further, the first to third compensation layers (245, 244, and 242) may be formed of a hole transport material, or may be formed of the same material as a host included in the blue light emitting layer 253, the green light emitting layer 252, and the red light emitting layer 251 that are adjacent to each other in each light emitting device.

Further, a capping layer 280 may be further provided on the second electrode 270 to protect the respective light emitting devices, and to increase the emission efficiency of light emitted from the second electrode 270. The capping layer 280 may include at least one of an organic capping layer or an inorganic capping layer. The capping layer 280 may be formed by stacking a plurality of capping layers having different refractive indices to maximize or increase the emission effect.

The color filter layer 290 may be provided in contact with the capping layer 280. Alternatively, an encapsulation layer may be further formed on the capping layer 280, and the color filter layer 290 may be formed on the encapsulation layer.

The encapsulation layer may include a first inorganic encapsulation layer, a second organic encapsulation layer, and a third inorganic encapsulation layer sequentially stacked.

The first inorganic encapsulation layer and the third inorganic encapsulation layer may be made of an inorganic material such as silicon oxide (SiO_{X}) or silicon nitride (SiN_{X}). The second organic encapsulation layer may be made of an organic material such as acrylic resin, epoxy resin, phenolic resin, polyamide resin, and polyimide resin. Materials of the first inorganic encapsulation layer, the second organic encapsulation layer and the third inorganic encapsulation layer are not limited thereto.

Meanwhile, the encapsulation layer is not limited to three layers, for example, the encapsulation layer may include n layers alternately stacked between inorganic encapsulation layer and organic encapsulation layer (where n is an integer greater than 3).

A second area of the first electrodes (220a, 220b, 220c, and 220d) that overlap a bank 230 is positioned on a side slope of the emission extension defining layer 217. Accordingly, since light generated in intermediate layers between the first electrodes (220a, 220b, 220c, and 220d) and the second electrode 270 is reflected from the second area of the first electrodes (220a, 220b, 220c, and 220d) on the side slope of the emission extension defining layer 217, the second area of the first electrodes (220a, 220b, 220c, and 220d) may be considered a side mirror.

The light emitting display device according to this embodiment of the present disclosure also has an advantage in that the light emission effect is improved by the reflection effect by the side mirror and light emission is generated even in an area that overlaps the bank 230, thereby making it possible to increase the resolution.

Further, configurations and functions of a red light emitting device that emits red light, a green light emitting device that emits green light, and a blue light emitting device that emits blue light according to this embodiment of the present disclosure are the same as those described with reference to FIGS. 4 to 6, and thus, description thereof will not be repeated.

On the substrate 200, a thin film transistor (TFT) including a gate electrode 204, a semiconductor layer 203 with a gate insulating layer 205 interposed between the semiconductor layer 203 and the gate electrode 204, and a source electrode and a drain electrode 211 connected to both sides of the semiconductor layer 203 is provided.

One of the source electrode and the drain electrode 211 may be connected to each of the first electrodes (130a, 130b, 130c, and 130d) of the first to fourth light emitting devices (R_SP, G_SP, B_SP, and W_SP).

The semiconductor layer 203 may be formed of, for example, at least one of an oxide semiconductor material, an amorphous semiconductor material, a polycrystalline semiconductor material and an organic semiconductor material, but the present disclosure is not limited thereto.

The oxide semiconductor material may have an excellent effect of preventing a leakage current and relatively inexpensive manufacturing cost. The oxide semiconductor may be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor may be made of polycrystalline silicon (poly-Si), but is not limited thereto.

The amorphous semiconductor material may be made of amorphous silicon (a-Si), but is not limited thereto.

The organic semiconductor material may include metal-organic compounds, but is not limited thereto.

Further, at least on a lower side of the channel region of the semiconductor layer 203, a light blocking layer 201 for preventing abnormal operation of the semiconductor layer 203 due to light coming from the lower side of the substrate 200 may be further provided.

A buffer layer 202 may be provided between the light blocking layer 201 and the semiconductor layer 203.

An interlayer insulating layer 206 may be further provided between the gate electrode 204 and the source/drain electrodes 211.

A planarization layer 215 may be provided to protect the thin film transistor TFT. Additionally, an inorganic protecting film may be further provided between the thin film transistor TFT and the planarization layer 215.

The emission extension defining layer 217 is further provided on the planarization layer 215, and the light emission effect by side reflection can be achieved through the first electrodes (220a, 220b, 220c, and 220d) positioned on the side of the emission extension definition layer 217 in the overlapping area with respect to the bank 230.

Here, the bank 230 is provided to cover the emission extension defining layer 217 and the inclined portions of the first electrodes (220a, 220b, 220c, and 220d).

A first area of the first electrodes (220a, 220b, 220c, and 220d) where the bank 230 is exposed is a flat area, in which light generated in each intermediate layer can be transmitted in a vertical direction.

In the light emitting display device of the present disclosure, side emission can be achieved through the inclined portion extending from the first electrode (anode) in the area that overlaps the bank, so that the light emitting area can be extended to realize high resolution.

In the light emitting display device of the present disclosure, in order to prevent color mixing by adjacent extended light emitting parts in the structure where side emission can be achieved, the vertical phases of the light emitting layers in the intermediate layers provided in respective sub-pixels are set differently. In this way, since vertical phases of adjacent light emitting layers in adjacent light emitting parts are different, it is possible to prevent side leakage current from being generated through the light emitting layers.

In the light emitting display device according to the present disclosure, since the red light emitting layer, the green light emitting layer, and the blue light emitting layer are sequentially disposed commonly on the first electrodes in the light emitting devices that emit light of different colors, and the energy band gaps between the red/green/blue light emitting layers are set differently so that the turn-on voltages are different, it is possible to prevent energy loss due to overlapping other color light emitting layers in the light emitting device that emits light of a predetermined or selected color. In addition, even in a case where side light due to adjacent other color light emitting parts enters, due to a difference in energy band gaps that cause excitation emission, mixed color light emission by the side light is not generated.

As is apparent from the above description, according to the present disclosure, the light emitting display device of the present disclosure has the following effects.

First, side emission can be achieved through the inclined part that is extended from the first electrode (anode) in the area that overlaps the bank, thereby making it possible to extend a light emitting area to achieve high resolution.

Second, in order to prevent color mixing by adjacent extended light emitting parts in the structure where side emission can be achieved, the vertical phases of the light emitting layers in the intermediate layers provided in the respective sub-pixels are set differently. In this way, since the vertical phases of the adjacent light emitting layers in the adjacent light emitting parts are different, it is possible to prevent side leakage current from being generated through the light emitting layers.

Third, since the red light emitting layer, the green light emitting layer, and the blue light emitting layer are sequentially disposed commonly on the first electrodes in the light emitting devices that emit light of different colors, and the energy band gaps between the red/green/blue light emitting layers are different so that the turn-on voltages are different, energy loss does not occur in other overlapping color light emitting layers in the light emitting device that emits light of a predetermined or selected color. In addition, even in a case where side light due to adjacent other color light emitting parts enters, due to a difference in energy band gaps that cause excitation emission, mixed color light emission by the side light is not generated.

Fourth, since the red light emitting layer, the green light emitting layer, and the blue light emitting layer that are sequentially disposed commonly on the first electrodes in the light emitting devices that emit light of different colors, and the vertical positions of light emitted by the respective light emitting devices are secured using compensation layers, it is possible to reduce the number of fine metal masks (FMM) having a fine opening compared with the structure in which respective color light emitting layers and optical compensation layers are used together, thereby improving yield.

Fifth, in the structure having the side mirror, since the vertical positions of the respective light emitting devices are differently set due to common disposition of color light emitting layers and thickness adjustment of the compensation layers, it is possible to manufacture a reliable light emitting display device without adding a separate material. In addition, there is an advantage in that low-power driving and efficiency improvement are simultaneously achieved by preventing side leakage current and utilizing the extended light emitting parts by the side mirror. Accordingly, an ESG (Environment/Social/Governance) effect can be achieved in terms of eco-friendliness, low power consumption, and process optimization.

A light emitting display device according to one or more aspects of the present disclosure may comprise a substrate including first to third sub-pixels and a first light emitting device at the first sub-pixel, a second light emitting device at the second sub-pixel, and a third light emitting device at the third sub-pixel, the first to third light emitting device to emit light of different wavelengths. The first light emitting device, the second light emitting device, and the third light emitting device may comprise a first intermediate layer, a second intermediate layer, and a third intermediate layer between a first electrode and a second electrode that face each other, respectively. The first intermediate layer, the second intermediate layer, and the third intermediate layer may comprise a red light emitting layer, a green light emitting layer, and a blue light emitting layer in order on the first electrode. Also, the blue light emitting layer of the first intermediate layer may have a vertical phase higher than those of the blue light emitting layers of the second intermediate layer and the third intermediate layer.

In a light emitting display device according to one or more aspects of the present disclosure, the first intermediate layer may further comprise a first compensation layer between the green light emitting layer and the blue light emitting layer, the second intermediate layer may further comprise a second compensation layer between the red light emitting layer and the green light emitting layer, and the third intermediate layer may further comprise a third compensation layer between the first electrode and the red light emitting layer.

In a light emitting display device according to one or more aspects of the present disclosure, the first compensation layer may have a greater thickness than each of thicknesses of the second compensation layer and the third compensation layer.

In a light emitting display device according to one or more aspects of the present disclosure, the second compensation layer may extend to the first intermediate layer.

In a light emitting display device according to one or more aspects of the present disclosure, the first intermediate layer, the second intermediate layer, and the third intermediate layer may further comprise a hole injection layer and a hole transport layer between the first electrode and the red light emitting layer, and may further comprise an electron transport layer and an electron injection layer between the blue light emitting layer and the second electrode.

In a light emitting display device according to one or more aspects of the present disclosure, the blue light emitting layer may be positioned at a second anti-node in the first intermediate layer, and each of the green light emitting layer of the second intermediate layer and the red light emitting layer of the third intermediate layer may be positioned at a first anti-node.

In a light emitting display device according to one or more aspects of the present disclosure, among the blue light emitting layer, the green light emitting layer, and the red light emitting layer, the blue light emitting layer may have the highest turn-on voltage, and the red light emitting layer has the lowest turn-on voltage.

In a light emitting display device according to one or more aspects of the present disclosure, the first electrode of each of the first light emitting device, the second light emitting device, and the third light emitting device may comprise a first area provided on an upper surface of a planarization layer, and a second area provided on an emission extension defining layer having a side slope outside the first area.

A light emitting display device according to one or more aspects of the present disclosure may further comprise a bank to expose the first area of the first electrode, and cover the emission extension defining layer and the second area of the first electrode.

In a light emitting display device according to one or more aspects of the present disclosure, the emission extension defining layer may be positioned on the planarization layer, and the first electrode may be connected to a thin film transistor under the planarization layer through a contact hole to penetrate the emission extension defining layer and the planarization layer.

In a light emitting display device according to one or more aspects of the present disclosure, the first electrode may comprise a reflective electrode, and the second electrode may comprise a transparent electrode or a transflective electrode.

A light emitting display device according to one or more aspects of the present disclosure may further comprise a capping layer on the second electrode.

In a light emitting display device according to one or more aspects of the present disclosure, a fourth sub-pixel may be further provided on the substrate. The fourth sub-pixel may comprise a fourth light emitting device having the same structure as that of the third light emitting device, and a color filter may be provided on the second electrode of the fourth light emitting device.

In a light-emitting display device according to one or more aspects of the present disclosure, the first intermediate layer may have a greater thickness than a thickness of each of the second intermediate layer and the third intermediate layer.

A light-emitting display device according to one or more aspects of the present disclosure may further comprise a bank defining a light-emitting area of each of the first to third sub-pixels, wherein, in an area overlapping with the bank, at least a portion of the first electrode is disposed to be inclined relative to the substrate.

A light emitting display device according to one or more aspects of the present disclosure may comprise a substrate including first to third sub-pixels, a first light emitting device to emit light of a first wavelength at the first sub-pixel, a second light emitting device to emit light of a second wavelength longer than the first wavelength at the second sub-pixel and a third light emitting device to emit light of a third wavelength longer than the second wavelength at the third sub-pixel. The first light emitting device, the second light emitting device, and the third light emitting device may comprise a first intermediate layer, a second intermediate layer, and a third intermediate layer between a first electrode and a second electrode that face each other, respectively. The first intermediate layer, the second intermediate layer, and the third intermediate layer may comprise a red light emitting layer, a green light emitting layer, and a blue light emitting layer in order on the first electrode. In the light emitting display device, the blue light emitting layer of the first intermediate layer has a vertical phase higher than those of the blue light emitting layers of the second intermediate layer and the third intermediate layer.

A light emitting display device according to one or more aspects of the present disclosure may comprise a substrate including a first sub-pixel, a second sub-pixel, a third sub-pixel, a fourth sub-pixel, first electrodes spaced apart from each other in the first to fourth sub-pixels, a first intermediate layer on the first electrode, corresponding to the first sub-pixel and the fourth sub-pixel, a second intermediate layer on the first electrode, corresponding to the second sub-pixel, a third intermediate layer on the first electrode, corresponding to the third sub-pixel and a second electrode on the first to third intermediate layers. The first intermediate layer, the second intermediate layer, and the third intermediate layer may comprise a red light emitting layer, a green light emitting layer, and a blue light emitting layer in order on the first electrode. In the light emitting display device, the blue light emitting layer of the first intermediate layer may have a vertical phase higher than those of the blue light emitting layers of the second intermediate layer and the third intermediate layer.

A light emitting display device according to one or more aspects of the present disclosure may further comprise a white color filter on the second electrode, corresponding to the fourth sub-pixel.

In a light emitting display device according to one or more aspects of the present disclosure, the first intermediate layer may further comprise a first compensation layer between the green light emitting layer and the blue light emitting layer, the second intermediate layer may further comprise a second compensation layer between the red light emitting layer and the green light emitting layer, and the third intermediate layer may further comprise a third compensation layer between the first electrode and the red light emitting layer.

In a light emitting display device according to one or more aspects of the present disclosure, the first compensation layer may have a greater thickness than each of thicknesses of the second compensation layer and the third compensation layer.

In a light emitting display device according to one or more aspects of the present disclosure, the blue light emitting layer may be positioned at a second anti-node in the first intermediate layer, and each of the green light emitting layer of the second intermediate layer and the red light emitting layer of the third intermediate layer may be positioned at a first anti-node.

In a light emitting display device according to one or more aspects of the present disclosure, among the blue light emitting layer, the green light emitting layer, and the red light emitting layer, the blue light emitting layer may have the highest turn-on voltage, and the red light emitting layer may have the lowest turn-on voltage.

In a light emitting display device according to one or more aspects of the present disclosure, the first electrode of each of the first to fourth sub-pixels may comprise a first area on an upper surface of a planarization layer, and a second area on a second planarization layer having a side slope outside the first area.

It will be apparent to those skilled in the art that various modifications and variations can be made in the present disclosure without departing from the spirit or scope of the disclosures. Thus, it is intended that the present disclosure covers the modifications and variations of this disclosure provided they come within the scope of the appended claims and their equivalents.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A light emitting display device, comprising:
a substrate including first, second and third sub-pixels; and
a first light emitting device at the first sub-pixel, a second light emitting device at the second sub-pixel, and a third light emitting device at the third sub-pixel, the first, second and third light emitting devices emitting light of different wavelengths,
wherein each of the first light emitting device, the second light emitting device and the third light emitting device includes a first intermediate layer, a second intermediate layer, and a third intermediate layer between a first electrode and a second electrode that face each other, respectively, and
wherein each of the first intermediate layer, the second intermediate layer, and the third intermediate layer includes a red light emitting layer, a green light emitting layer, and a blue light emitting layer in order on the first electrode, in which the blue light emitting layer of the first intermediate layer has a vertical phase higher than those of the blue light emitting layers of the second intermediate layer and the third intermediate layer.

2. The light emitting display device according to claim 1, wherein the first intermediate layer further comprises a first compensation layer between the green light emitting layer and the blue light emitting layer thereof,
wherein the second intermediate layer further comprises a second compensation layer between the red light emitting layer and the green light emitting layer thereof, and
wherein the third intermediate layer further comprises a third compensation layer between the first electrode and the red light emitting layer thereof.

3. The light emitting display device according to claim 2, wherein the first compensation layer has a greater thickness than each of thicknesses of the second compensation layer and the third compensation layer.

4. The light emitting display device according to claim 2, wherein the second compensation layer extends to the first intermediate layer.

5. The light emitting display device according to claim 1, wherein each of the first intermediate layer, the second intermediate layer and the third intermediate layer further includes a hole injection layer and a hole transport layer between the first electrode and the red light emitting layer, and an electron transport layer and an electron injection layer between the blue light emitting layer and the second electrode.

6. The light emitting display device according to claim 1, wherein:
the blue light emitting layer is positioned at a second anti-node in the first intermediate layer; and
each of the green light emitting layer of the second intermediate layer and the red light emitting layer of the third intermediate layer is positioned at a first anti-node.

7. The light emitting display device according to claim 1, wherein among the blue light emitting layer, the green light emitting layer and the red light emitting layer, the blue light emitting layer has the highest turn-on voltage and the red light emitting layer has the lowest turn-on voltage.

8. The light emitting display device according to claim 1, wherein the first electrode of each of the first light emitting device, the second light emitting device and the third light emitting device comprises a first area provided on an upper surface of a first planarization layer, and a second area provided on a second planarization layer having a side slope outside the first area.

9. The light emitting display device according to claim 8, further comprising a bank to expose the first area of the first electrode and cover the second planarization layer and the second area of the first electrode.

10. The light emitting display device according to claim 8, wherein:
the second planarization layer is positioned on the first planarization layer; and
the first electrode is connected to a thin film transistor under the first planarization layer through a contact hole to penetrate the second planarization layer and the planarization layer.

11. The light emitting display device according to claim 1, wherein:
the first electrode comprises a reflective electrode; and
the second electrode comprises a transparent electrode or a transflective electrode.

12. The light emitting display device according to claim 1, further comprising a capping layer on the second electrode.

13. The light-emitting display device according to claim 1, wherein the first intermediate layer has a greater thickness than a thickness of each of the second intermediate layer and the third intermediate layer.

14. The light emitting display device according to claim 1, wherein:
a fourth sub-pixel is further provided on the substrate;
the fourth sub-pixel comprises a fourth light emitting device having a same structure as that of the third light emitting device; and
a color filter is provided on the second electrode of the fourth light emitting device.

15. A light emitting display device, comprising:
a substrate including first, second and third sub-pixels;
a first light emitting device to emit light of a first wavelength at the first sub-pixel;
a second light emitting device to emit light of a second wavelength longer than the first wavelength at the second sub-pixel; and
a third light emitting device to emit light of a third wavelength longer than the second wavelength at the third sub-pixel,
wherein each of the first light emitting device, the second light emitting device, and the third light emitting device includes a first intermediate layer, a second intermediate layer and a third intermediate layer between a first electrode and a second electrode that face each other, respectively, and
wherein each of the first intermediate layer, the second intermediate layer and the third intermediate layer includes a red light emitting layer, a green light emitting layer and a blue light emitting layer in order on the first electrode, in which the blue light emitting layer of the first intermediate layer has a vertical phase higher than those of the blue light emitting layers of the second intermediate layer and the third intermediate layer.

16. A light emitting display device, comprising:
a substrate including a first sub-pixel, a second sub-pixel, a third sub-pixel and a fourth sub-pixel;
a plurality of first electrodes spaced apart from each other in the first, second, third and fourth sub-pixels;
a first intermediate layer on the first electrode, corresponding to the first sub-pixel and the fourth sub-pixel;
a second intermediate layer on the first electrode, corresponding to the second sub-pixel;
a third intermediate layer on the first electrode, corresponding to the third sub-pixel; and
a second electrode on the first, second and third intermediate layers,
wherein each of the first intermediate layer, the second intermediate layer and the third intermediate layer includes a red light emitting layer, a green light emitting layer and a blue light emitting layer in order on the first electrode, in which the blue light emitting layer of the first intermediate layer has a vertical phase higher than those of the blue light emitting layers of the second intermediate layer and the third intermediate layer.

17. The light emitting display device according to claim 16, further comprising a white color filter on the second electrode, corresponding to the fourth sub-pixel.

18. The light emitting display device according to claim 16, wherein:
the first intermediate layer further comprises a first compensation layer between the green light emitting layer and the blue light emitting layer thereof;
the second intermediate layer further comprises a second compensation layer between the red light emitting layer and the green light emitting layer thereof; and
the third intermediate layer further comprises a third compensation layer between the first electrode and the red light emitting layer thereof.

19. The light emitting display device according to claim 18, wherein the first compensation layer has a greater thickness than each of thicknesses of the second compensation layer and the third compensation layer.

20. The light emitting display device according to claim 16, wherein:
the blue light emitting layer is positioned at a second anti-node in the first intermediate layer; and
each of the green light emitting layer of the second intermediate layer and the red light emitting layer of the third intermediate layer is positioned at a first anti-node.

21. The light emitting display device according to claim 16, wherein among the blue light emitting layer, the green light emitting layer and the red light emitting layer, the blue light emitting layer has the highest turn-on voltage and the red light emitting layer has the lowest turn-on voltage.

22. The light emitting display device according to claim 16, wherein the first electrode of each of the first, second, third and fourth sub-pixels comprises a first area on an upper surface of a first planarization layer, and a second area on an second planarization layer having a side slope outside the first area.
